(19) United States
(12) Patent Application Publication
(10) Pub. No.: US 2014/0082449 A1
(43) Pub. Date: Mar. 20, 2014

(54) LDPC Decoder With Variable Node Hardening

(71) Applicant: Fan Zhang, Milpitas, CA (US)

(72) Inventor: Fan Zhang, Milpitas, CA (US)

(21) Appl. No.: 13/622,294

(22) Filed: Sep. 18, 2012

(51) Int. Cl. H03M 13/00; H03M 13/05

(52) U.S. Cl. 714/752; 714/800; 714/E11.002; 714/E11.03

(57) ABSTRACT

The present inventions are related to systems and methods for an LDPC decoder with variable node hardening, and in particular, to an LDPC decoder that temporarily hardens the value of a variable node by using check node to variable node (C2V) messages from a previous iteration that are likely to be correct when generating variable node to check node (V2C) messages.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, in perhaps the simplest system, a parity bit can be added to a group of data bits, ensuring that the group of data bits (including the parity bit) has either an even or odd number of ones. When using odd parity, as the data is prepared for storage or transmission, the number of data bits in the group that are set to one are counted, and if there is an even number of ones in the group, the parity bit is set to one to ensure that the group has an odd number of ones. If there is an odd number of ones in the group, the parity bit is set to zero to ensure that the group has an odd number of ones. After the data is retrieved from storage or received from transmission, the parity can again be checked, and if the group has an even parity, at least one error has been introduced in the data. At this simplistic level, some errors can be detected but not corrected.

The parity bit may also be used in error correction systems, including in Low Density Parity Check (LDPC) decoders. An LDPC code is a parity-based code that can be visually represented in a Tanner graph 100 as illustrated in FIG. 1. In an LDPC decoder, multiple parity checks are performed in a number of check nodes 102, 104, 106 and 108 for a group of variable nodes 110, 112, 114, 116, 118, 120, 122, and 124. The connections (or edges) between variable nodes 110-124 and check nodes 102-108 are selected as the LDPC code is designed, balancing the strength of the code against the complexity of the decoder required to execute the LDPC code as data is obtained. The number and placement of parity bits in the group are selected as the LDPC code is designed. Messages are passed between connected variable nodes 110-124 and check nodes 102-108 in an iterative process, passing beliefs about the values that should appear in variable nodes 110-124 to connected check nodes 102-108. Parity checks are performed in the check nodes 102-108 based on the messages and the results are returned to connected variable nodes 110-124 to update the beliefs if necessary. LDPC decoders may be implemented in binary or non-binary fashion. In a binary LDPC decoder, variable nodes 110-124 contain scalar values based on a group of data and parity bits that are retrieved from a storage device, received by a transmission system or obtained in some other way. Messages in the binary LDPC decoders are scalar values transmitted as plain-likelihood probability values or log-likelihood-ratio (LLR) values representing the probability that the sending variable node contains a particular value. In a non-binary LDPC decoder, variable nodes 110-124 contain symbols from a Galois Field, a finite field GF(p^{k}) that contains a finite number of elements, characterized by size p^{k} where p is a prime number and k is a positive integer. Messages in the non-binary LDPC decoders are multi-dimensional vectors, generally either plain-likelihood probability vectors or LLR vectors.

The connections between variable nodes 110-124 and check nodes 102-108 may be presented in matrix form as follows, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}a ( 1 , 1 ) & 0 & 0 & a ( 1 , 2 ) & 0 & a ( 1 , 3 ) & a ( 1 , 4 ) & 0 \\ 0 & a ( 2 , 1 ) & 0 & 0 & a ( 2 , 2 ) & 0 & 0 & a ( 2 , 3 ) \\ a ( 3 , 1 ) & 0 & a ( 3 , 2 ) & 0 & a ( 3 , 3 ) & a ( 3 , 4 ) & 0 & a ( 3 , 5 ) \\ 0 & a ( 4 , 1 ) & 0 & a ( 4 , 2 ) & 0 & 0 & a ( 4 , 3 ) & a ( 4 , 4 )\end{matrix} ]$$

By providing multiple check nodes 102-108 for the group of variable nodes 110-124, redundancy in error checking is provided, enabling errors to be corrected as well as detected. Each check node 102-108 performs a parity check on bits or symbols passed as messages from its neighboring (or connected) variable nodes. In the example LDPC code corresponding to the Tanner graph 100 of FIG. 1, check node 102 checks the parity of variable nodes 110, 116, 120 and 122. Values are passed back and forth between connected variable nodes 110-124 and check nodes 102-108 in an iterative process until the LDPC code converges on a value for the group of data and parity bits in the variable nodes 110-124. For example, variable node 110 passes messages to check nodes 102 and 106. Check node 102 passes messages back to variable nodes 110, 116, 120 and 122. The messages between variable nodes 110-124 and check nodes 102-108 are probabilities or beliefs, thus the LDPC decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As local decoding iterations are performed in the system, messages pass back and forth between variable nodes 110-124 and check nodes 102-108, with the values in the nodes 102-124 being adjusted based on the messages that are passed, until the values converge and stop changing or until processing is halted.

The passing of correct messages enables the LDPC decoder to detect and correct errors in the data. However, the passing of incorrect messages based on erroneous data slows the decoding process.

### BRIEF SUMMARY

The present inventions are related to systems and methods for an LDPC decoder with variable node hardening, and in particular, to an LDPC decoder that temporarily hardens the value of a variable node by using check node to variable node (C2V) messages from a previous iteration that are likely to be correct when generating variable node to check node (V2C) messages. When a C2V message in a particular decoding iteration is determined to be correct with a high probability, that C2V message is used in later iterations when generating V2C messages. The effect of the previous C2V is applied to later V2C message generation using a decaying scaling factor, gradually reducing the effect of the previous C2V message on later V2C message generation. The application of a previous likely correct C2V message on V2C message generation correlates messages from previous iterations and a current iteration to harden the V2C messages. This temporarily locks down the values of messages that are most probably correct so that they will influence the less probably correct messages for some decoding iterations before the incorrect messages can influence the correct message.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a Tanner graph of an example prior art LDPC code;

FIG. 2A depicts a portion of a Tanner graph with a check node to variable node message passing from a check node to a variable node;

FIG. 2B depicts a portion of a Tanner graph with a variable node to check node message passing from a variable node to a check node;

FIG. 3 depicts plots of the probability that a variable node has a correct value when all incoming C2V messages match (upper plot) and of the probability that a variable node has an incorrect value when all incoming C2V messages match (lower plot) in accordance with some embodiments of the present inventions;

FIG. 4 depicts a plot of an example decaying scaling factor that may be used to apply a C2V message when generating V2C messages in later decoding iterations in accordance with some embodiments of the present inventions;

FIG. 5 depicts a read channel for a hard disk drive, incorporating an LDPC decoder with variable node hardening in accordance with some embodiments of the present inventions;

FIG. 6 depicts a block diagram of an LDPC decoder with variable node hardening in accordance with some embodiments of the present inventions;

FIG. 7 depicts a block diagram of a multi-level min-sum based LDPC decoder with variable node hardening in accordance with some embodiments of the present inventions;

FIG. 8 depicts a flow diagram of an LDPC decoding operation with variable node hardening in accordance with some embodiments of the present inventions;

FIG. 9 depicts a storage system including a data processing circuit with an LDPC decoder with variable node hardening in accordance with some embodiments of the present inventions; and

FIG. 10 depicts a wireless communication system including a data processing circuit with an LDPC decoder with variable node hardening in accordance with some embodiments of the present inventions.

### DETAILED DESCRIPTION OF THE INVENTION

The present inventions are related to systems and methods for an LDPC decoder with variable node hardening, and in particular, to an LDPC decoder that temporarily hardens the value of a variable node by using check node to variable node (C2V) messages from a previous iteration that are likely to be correct when generating variable node to check node (V2C) messages. The LDPC decoder used in various embodiments may be any type of LDPC decoder, including binary and non-binary, layered and non-layered, non-erasure channel or erasure channel. LDPC technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

During traditional belief-propagation (BP) decoding of an LDPC code, LLR V2C and C2V messages are passed along the edges in the Tanner graph between check nodes and variable nodes. In each local iteration, the V2C and C2V messages on an edge are recalculated regardless of previous values on that edge. Because messages are interconnected through the Tanner graph, they influence each other more and more in successive decoding iterations and the correlation between messages increases. Just as correct messages influence incorrect messages, incorrect messages will also influence correct messages.

In the LDPC decoder with variable node hardening, messages along an edge may be correlated with messages from previous iterations. This temporarily locks down the values of messages that are most probably correct so that they will influence the less probably correct messages for some decoding iterations before the incorrect messages can influence the correct messages. When a C2V message in a particular decoding iteration is determined to be correct with a high probability, that C2V message is used in later iterations when generating V2C messages. The effect of the previous C2V is applied to later V2C message generation using a decaying scaling factor, gradually reducing the effect of the previous C2V message on later V2C message generation. The application of a previous likely correct C2V message on V2C message generation correlates messages from previous iterations and a current iteration to harden the V2C messages. By introducing memories along the decoding iterations, the LDPC decoder stores values which are likely to be correct, and biases the LLR messages of later iterations.

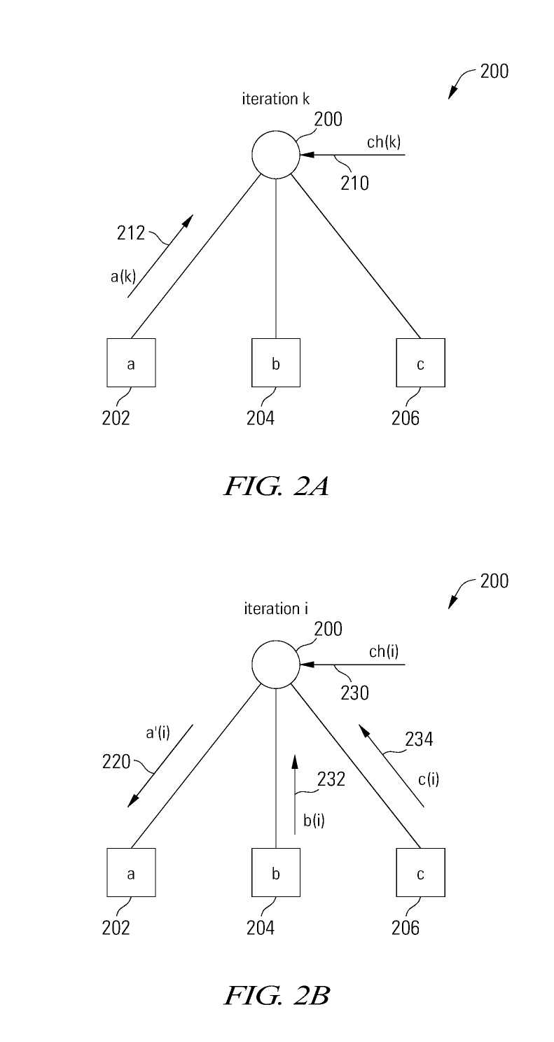

Turning to FIGS. 2A and 2B, a portion of a Tanner graph illustrates the V2C and C2V messages between a variable node 200 and its connected check nodes 202, 204, 206. In particular, FIGS. 2A and 2B give an example of the generation of a hardened V2C message a′(i) 220 in iteration i based in part on C2V message a(k) 212 in iteration k. In FIG. 2A, C2V message a(k) 212 from check node “a” 202 to variable node 200 is shown during iteration k. During a variable node update, the value of variable node 200 would be updated based on a channel data value 210 and on C2V messages from check nodes 202, 204 and 206, including C2V message a(k) 212. (C2V messages are also provided from check nodes 204 and 206, but are not shown because the generation of V2C message a′(i) 220 is not based on C2V messages from check nodes 204 and 206 in iteration k.)

During a normal decoding operation, the V2C message a′(i) 220 of FIG. 2B is generated in iteration i by adding the channel data ch(i) for iteration i to the C2V message b(i) 232 from check node 204 to variable node 200 and C2V message c(i) 234 from check node 206 to variable node 200. In other terms, a′(i)=ch(i)+b(i)+c(i). In the LDPC decoder with variable node hardening, if it is determined that a C2V message a(k) is correct with high probability in iteration k, the message a(k) is taken into account when generating V2C message a′(i) for all i>=k. Thus, with variable node hardening, the V2C message a′(i) 220 of FIG. 2B is generated in iteration i by adding the channel data ch(i) for iteration i to the C2V message b(i) 232 from check node 204 to variable node 200 and C2V message c(i) 234 from check node 206 to variable node 200, and to a scaled version of a(k). In other terms, a′(i)=ch(i)+b(i)+c(i)+t(i−k)*a(k), where t(i−k) is a decaying scaling factor to reduce the effect of a(k) gradually over successive decoding iterations. Scaling factor t varies in some embodiments from 0 to 1. The smaller the value of i−k, the larger the value of function t, and the more influence a(k) has on a′(i). This applies the probably-correct message a(k) most strongly in iterations at and just after iteration k, and less strongly in later iterations.

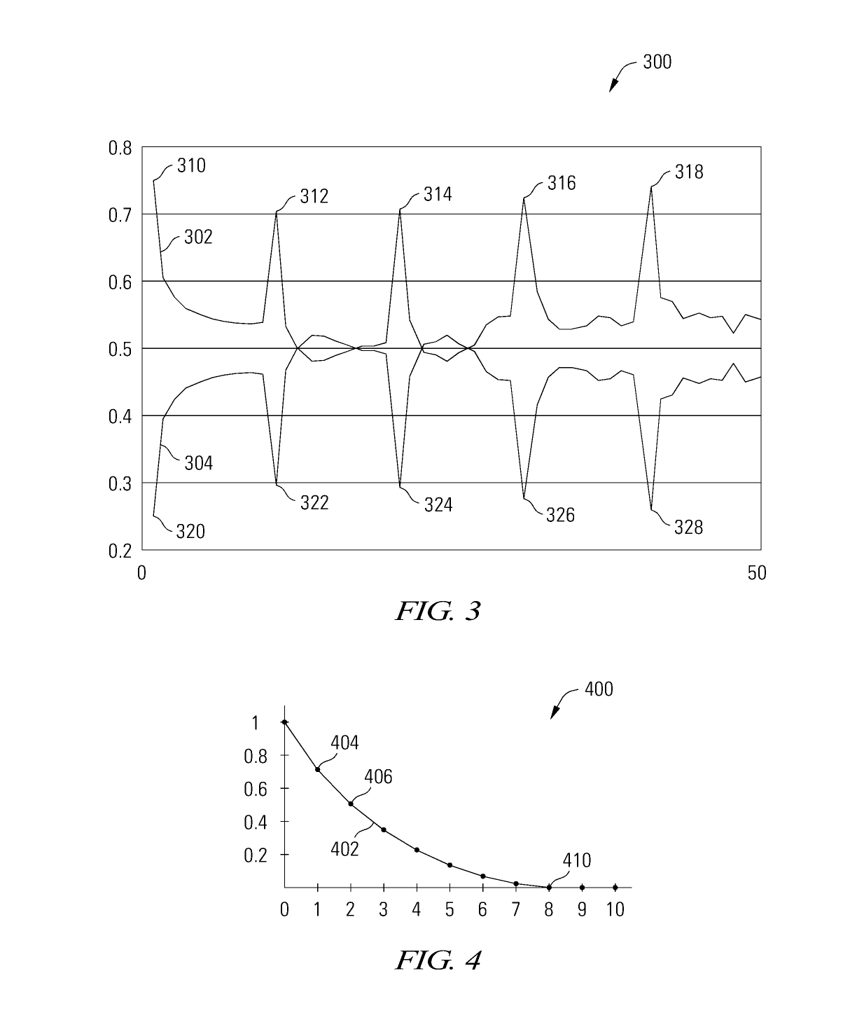

The C2V message a(k) 212 that is most probably correct may be identified in any suitable manner for storage and later use in generating V2C message a′(i) 220. C2V message a(k) 212 is most probably correct when the value or hard decision in variable node 200 is most probably correct. In some embodiments, the C2V message a(k) 212 that is most probably correct is identified by finding the iteration k in which the value in variable node 200 is most probably correct. Turning to FIG. 3, a graph 300 shows the probability 302 that a variable node (e.g., 200) has a correct value when all C2V messages (e.g., 212) from connected check nodes (e.g., 202, 204, 206) are in agreement. Graph 300 also shows the probability 304 that a variable node (e.g., 200) has an incorrect perceived value when all incoming C2V messages (e.g., 212) are in agreement. The X-axis corresponds to the iteration number, and the Y-axis corresponds to the probability, thus varying between 0 and 1. Note that the probability that a variable node has an incorrect value and the probability that the variable node has a correct value sums to 1 at any given iteration number. In this example, the graph 300 covers about 50 iterations, including 5 global iterations and 10 local iterations per global iteration. (A local iteration is a decoding pass on input data performed within an LDPC decoder, a global iteration is a data processing pass within a data processing system that includes the LDPC decoder as well as other data processing components.)

At certain global and local iterations, agreement between incoming check node messages is more likely than in other iterations to correspond with a high probability that the value of the variable node is correct. This means that there is better correlation between probability of an incorrect value in a variable node and received C2V message disagreement at these particular iterations. As shown in FIG. 3, the best correlation between probability of incorrect perceived variable node value and C2V message disagreement is at the first local iteration of each global iteration, taking place at iterations 1, 11, 21, 31 and 41 in this example. The separation between the probability of correct value and incorrect value when C2V messages are matching is greatest at the first local iteration of each global iteration, illustrated by the corresponding peaks 410, 312, 314, 316 and 318 in probability 300 and the valleys 320, 322, 324, 326 and 328 of probability 304. This is because local iterations in the LDPC decoder increase the correlation between C2V messages received by a variable node, while external processing such as in a Viterbi detector during global iterations increases the independence of values in the LDPC decoder and thus of the messages passed in the LDPC decoder. When the C2V messages are most independent, a disagreement or conflict between the C2V messages received by a variable node is most likely to be a correct indication that the perceived value in the variable node is incorrect.

Again, the probability 302 is the probability that the value of a variable node is correct when all received C2V messages match. Notably, this is not simply the probability that the perceived value in a variable node is correct, but the probability that the received C2V messages are correct in indicating that the value of the variable node is correct. This probability is highest when the check nodes are most independent, that is, their votes carry more weight or are most valid when they are the most independent of voters. After multiple local iterations in the LDPC decoder, each check node has been influenced by other check nodes, so it is less probable when they all vote the same way that the outcome is correct.

Given an LDPC decoder that yields a decoding result or simulated result as in FIG. 3, the variable nodes with matching incoming C2V messages are correct with high probability at the first local iteration of each global iteration, and so are the corresponding C2V messages. In this example embodiment, the first local iteration of each global iteration is selected as iteration k, and C2V messages (e.g., a(k) 212) are stored for use in generating later V2C messages (e.g., a′(i) 220) if the C2V messages for all connected check nodes 202, 204, 206 are in agreement about the value of the variable node 200. The selection of the first local iteration of each global iteration as iteration k from which C2V messages (e.g., a(k) 212) are stored may be done during the design process for the LDPC decoder using decoding simulations to identify patterns as shown in FIG. 3. In some other embodiments, the selection of an iteration k may be performed during operation using quality metrics to identify the iteration k when C2V messages are likely correct with a higher probability than in other iterations.

Turning to FIG. 4, a graph 400 illustrates a plot of an example function 402 used to specify the decaying scaling factors t(i−k) that weight the C2V message a(k) 212 used to generate a V2C message a′(i) 220. In this example, the function 402 starts with a value of 1 when iterations i−k=0, decreasing gradually to a value 410 of about 0 at iteration i−k=8. Again, t(i−k) is a decaying scaling factor used to reduce the effect of a(k) gradually over successive decoding iterations, decreasing over time from a maximum value of 1 to a minimum value of 0. The decaying function may be any suitable function, such as a linear function, a geometric or exponential curve, etc. The decaying function may be tuned to provide desired results using channel test data in an LDPC decoder or simulation, for example repeatedly running the same test data while applying various decaying functions to observe the effect on convergence and the number of unsatisfied parity checks. The decaying function may be implemented by calculating an equation to yield the proper scaling value at each iteration, or may be hardwired in the LDPC decoder design, or may use a lookup table to provide the proper scaling factor based on the iteration number. For example, if there are only 10 local iterations per global iteration, and if the variable node hardening starts over at every global iteration, that is, if the variable node hardening procedure is self-contained or limited within a single global iteration, the decaying scaling factor t(i−k) only has up to 10 values, one per local iteration within a global iteration. The example curve 402 in FIG. 4 may thus be implemented using an equation to describe the line and yield the scaling values 404, 406, and 410, for example, at iterations 1, 2, and 8, or using a lookup table storing the 10 scaling values.

Again, the variable node hardening applies C2V message a(k) 212 to the generation of

V2C message a′(i) 220 if the C2V messages from check nodes 202, 204, 206 were in agreement in iteration k. This process is repeated in parallel or serial to generate the V2C messages from every variable node to every check node during each iteration, as applicable according to the particular decoding algorithm used in the LDPC decoder.

Turning to FIG. 5, a read channel 500 is depicted that includes an LDPC decoder with variable node hardening 532 in accordance with some embodiments of the present inventions. The read channel 500 processes an analog signal 502 to retrieve user data bits from the analog signal 502 without errors. In some cases, analog signal 502 is derived from a read/write head assembly in a magnetic storage medium. In other cases, analog signal 502 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 502 may be derived.

The read channel 500 includes an analog front end 504 that receives and processes the analog signal 502. Analog front end 504 may include, but is not limited to, an analog filter and an amplifier circuit as are known in the art. Based upon the disclosure provided herein, one of ordinary skill in the art will recognize a variety of circuitry that may be included as part of analog front end 504. In some cases, the gain of a variable gain amplifier included as part of analog front end 504 may be modifiable, and the cutoff frequency and boost of an analog filter included in analog front end 504 may be modifiable. Analog front end 504 receives and processes the analog signal 502, and provides a processed analog signal 506 to an analog to digital converter 510.

Analog to digital converter 510 converts processed analog signal 506 into a corresponding series of digital samples 512. Analog to digital converter 510 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present inventions. Digital samples 512 are provided to an equalizer 514. Equalizer 514 applies an equalization algorithm to digital samples 512 to yield an equalized output 516. In some embodiments of the present invention, equalizer 514 is a digital finite impulse response filter circuit as is known in the art. Data or codewords contained in equalized output 516 may be stored in a buffer 518 until a data detector 520 is available for processing.

The data detector 520 performs a data detection process on the received input, resulting in a detected output 522. In some embodiments of the present invention, data detector 520 is a Viterbi algorithm data detector circuit, or more particularly in some cases, a maximum a posteriori (MAP) data detector circuit as is known in the art. In these embodiments, the detected output 522 contains log-likelihood-ratio (LLR) information about the likelihood that each bit or symbol has a particular value. Based upon the disclosure provided herein, one of ordinary skill in the art will recognize a variety of data detectors that may be used in relation to different embodiments of the present invention. Data detector 520 is started based upon availability of a data set in buffer 518 from equalizer 514 or another source.

The detected output 522 from data detector 520 is provided to an interleaver 524 that protects data against burst errors. Burst errors overwrite localized groups or bunches of bits. Because LDPC decoders are best suited to correcting errors that are more uniformly distributed, burst errors can overwhelm LDPC decoders. The interleaver 524 prevents this by interleaving or shuffling the detected output 522 from data detector 520 to yield an interleaved output 526 which is stored in a memory 530. The interleaved output 526 from the memory 530 is provided to a LDPC decoder 532 which performs parity checks on the interleaved output 526, ensuring that parity constraints established by an LDPC encoder (not shown) before storage or transmission are satisfied in order to detect and correct any errors that may have occurred in the data during storage or transmission or during processing by other components of the read channel 500. As part of the decoding process, the LDPC decoder with variable node hardening 532 may harden variable node values by applying C2V messages that are highly probably correct when generating V2C messages for later decoding iterations.

Multiple detection and decoding iterations may be performed in the read channel 500, both global iterations through the detector 520 and LDPC decoder 532 and local iterations within the LDPC decoder 532. To perform a global iteration, LLR values 534 from the LDPC decoder 532 are stored in memory 530, deinterleaved in a deinterleaver 536 to reverse the process applied by interleaver 524, and provided again to the data detector 520 to allow the data detector 520 to repeat the data detection process, aided by the LLR values 534 from the LDPC decoder 532. In this manner, the read channel 500 can perform multiple global iterations, allowing the data detector 520 and LDPC decoder 532 to converge on the correct data values.

The LDPC decoder 532 also produces hard decisions 540 about the values of the data bits or symbols contained in the interleaved output 526 of the interleaver 524. For binary data bits, the hard decisions may be represented as 0's and 1's. In a GF(4) LDPC decoder, the hard decisions may be represented by four field elements 00, 01, 10 and 11.

The hard decisions 540 from LDPC decoder 532 are deinterleaved in a hard decision deinterleaver 542, reversing the process applied in interleaver 524, and stored in a hard decision memory 544 before being provided to a user or further processed. For example, the output 546 of the read channel 500 may be further processed to reverse formatting changes applied before storing data in a magnetic storage medium or transmitting the data across a transmission channel.

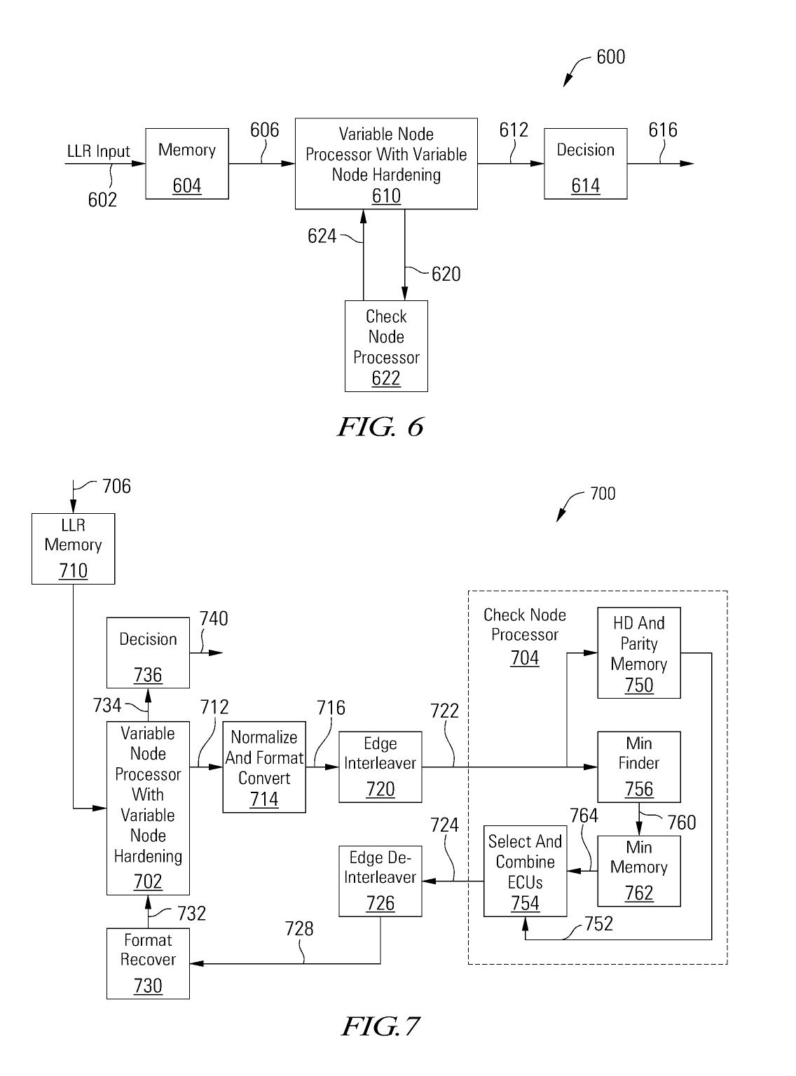

Turning to FIG. 6, a block diagram of an LDPC decoder with variable node hardening 600 is depicted in accordance with some embodiments of the present inventions. The LDPC decoder with variable node hardening 600 may be a binary or multi-level decoder, layered or non-layered, and is not limited to any particular algorithm for parity check calculations or message generation techniques. Input data 602 is stored in a memory 604. Input data 602 includes LLR values in some embodiments. LLR values 606 from memory 604 are provided to a variable node processor with variable node hardening 610, which generates V2C messages 620 containing LLR values for the perceived value of each variable node. The V2C messages 620 may be hardened as disclosed above, storing C2V messages that are highly probably correct, that is, in some embodiments, storing C2V messages that were in agreement with other C2V messages for a variable node during an iteration k selected as a best candidate iteration for providing C2V messages for storage. The stored C2V messages are then applied when generating V2C messages for later decoding iterations using a decaying scaling factor.

A check node processor 622 receives the V2C messages 620 and performs parity check calculations for each check node based on messages from connected variable nodes. The check node processor 622 also generates C2V messages 624, enabling the variable node processor 610 to update the perceived value for each variable node based on C2V messages 624 from connected check nodes. Updated variable node values may also be updated in the memory 604 during local decoding iterations, either by the variable node processor 610 or check node processor 622 or both. LLR values 612 from the variable node processor 610 may also be provided to a decision circuit 614 which generates a hard decision output 616.

Turning to FIG. 7, in some embodiments, the LDPC decoder with variable node hardening is a min-sum based LDPC decoder 700 in which check nodes calculate a minimum, next minimum and hard decision value based on incoming V2C or variable node message vectors. However, it is important to note that the LDPC decoder with variable node hardening is not limited to the min-sum based non-binary LDPC decoder 700 of FIG. 7, but that any suitable LDPC decoder may be operable to implement the dynamic graph modification disclosed herein.

The min-sum based non-binary LDPC decoder 700 is provided with an input 706, for example containing a hard decision and corresponding LLR values, which are stored in a symbol memory 710. The input 706 is provided to the variable node processor with variable node hardening 702 from the symbol memory 710, and the variable node processor 702 updates the perceived value of each symbol based on the value from input 706 and on C2V message vectors or check node messages from a check node processor 704. The variable node processor 702 also generates V2C message vectors 712 or variable node messages for neighboring check nodes. The V2C messages 712 may be hardened as disclosed above, storing C2V messages that are highly probably correct, that is, in some embodiments, storing C2V messages that were in agreement with other C2V messages for a variable node during an iteration k selected as a best candidate iteration for providing C2V messages for storage. The stored C2V messages are then applied when generating V2C messages for later decoding iterations using a decaying scaling factor.

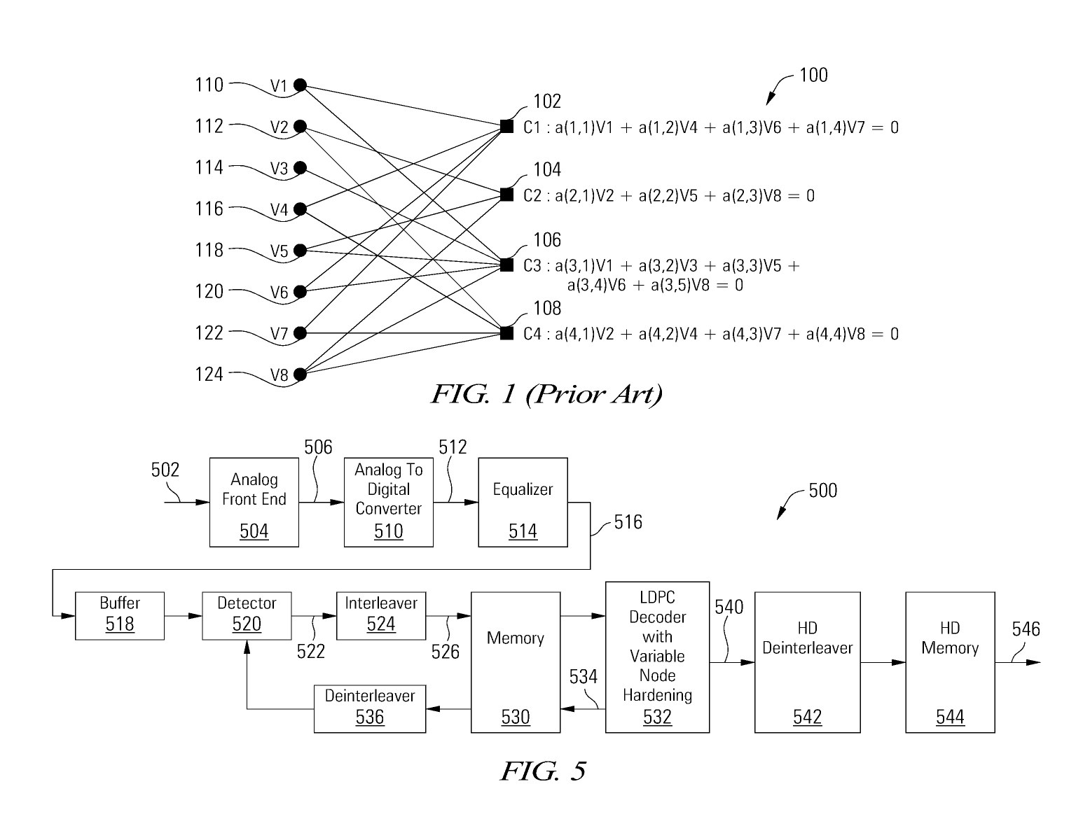

Check nodes (implemented in check node processor 704) in a min-sum based non-binary LDPC decoder receive incoming messages from connected or neighboring variable nodes (implemented in variable node processor 702) and generate outgoing messages to each neighboring variable node to implement the parity check matrix for the LDPC code, an example of which is graphically illustrated in the Tanner graph of FIG. 1. Incoming messages to check nodes are also referred to herein as V2C messages, indicating that they flow from variable nodes to check nodes, and outgoing messages from check nodes are also referred to herein as C2V messages, indicating that they flow from check nodes to variable nodes. The check node uses multiple V2C messages to generate an individualized C2V message with for each neighboring variable node.

In various embodiments of LDPC decoders that may be adapted to include variable node hardening, the variable node processor 702 and check node processor 704 may each be unitary, discrete components, or their functions may be distributed and intermixed in multiple components. The terms variable node processor and check node processor are therefore not limited to two discrete processing components, but apply generally to any components or combinations of components in an LDPC decoder that update variable node values and generate variable node to check node messages for variable node processing, and that perform check node constraint calculations and generate check node to variable node messages for check node processing.

Both V2C and C2V messages in this embodiment are vectors, each including a number of sub-messages with LLR values. Each V2C message vector from a particular variable node contains sub-messages corresponding to each symbol in the Galois Field, with each sub-message giving the likelihood that the variable node contains that particular symbol. For example, given a Galois Field GF(q) with q elements, V2C and C2V messages will include at least q sub-messages representing the likelihood for each symbol in the field.

Generally, the C2V vector message from a check node to a variable node contains the probabilities for each symbol d in the Galois Field that the destination variable node contains that symbol d, based on the prior round V2C messages from neighboring variable nodes other than the destination variable node. The inputs from neighboring variable nodes used in a check node to generate the C2V message for a particular neighboring variable node are referred to as extrinsic inputs and include the prior round V2C messages from all neighboring variable nodes except the particular neighboring variable node for which the C2V message is being prepared, in order to avoid positive feedback. The check node thus prepares a different C2V message for each neighboring variable node, using the different set of extrinsic inputs for each message based on the destination variable node.

In the min-sum based decoding disclosed herein, the check nodes calculate the minimum sub-message min₁(d), the index idx(d) of min₁(d), and the sub-minimum sub-message min₂(d), or minimum of all sub-messages excluding min₁(d), for each nonzero symbol din the Galois Field based on all extrinsic V2C messages from neighboring variable nodes. In other words, the sub-messages for a particular symbol d are gathered from messages from all extrinsic inputs, and the min₁(d), idx(d) and min₂(d) is calculated based on the gathered sub-messages for that symbol d. For a Galois Field with q symbols, the check node will calculate the min₁(d), idx(d) and min₂(d) sub-message for each of the q−1 non-zero symbols in the field except the most likely symbol.

The V2C message vectors 712 from the variable node processor 702 are provided to a message format converter 714 which converts the format of V2C message vectors 712 to a format consisting of two parts, the most likely symbol, and the LLR of other symbols, normalized to the most likely symbol, yielding normalized V2C message vectors 716 in the second format. Message normalization in the message format converter 714 is performed with respect to the most likely symbol. Thus, the V2C and C2V vector format includes two parts, an identification of the most likely symbol and the LLR for the other q−1 symbols, since the most likely symbol has LLR equal to 0 after normalization. The normalized V2C message vectors 716 are provided to an edge interleaver 720 which shuffles messages on the boundaries at message edges, randomizing noise and breaking dependencies between messages. The interleaved normalized V2C message vectors 722 are provided to the check node processor 704, which generates C2V messages 724 for each neighboring variable node processor based on extrinsic V2C messages from other neighboring variable node processors.

The C2V messages 724 are provided to an edge de-interleaver 726, which reverses the process of the edge interleaver 720, and then to a format recovery circuit 730, which converts message vectors from the second, normalized format to the first message vector format of the variable node processor 702, reversing the process of the message format converter 714. The resulting first format C2V messages 732 are provided to the variable node processor 702 for use in updating perceived LLR values in variable nodes. In other embodiments, the variable node processor 702 is adapted to operate directly with message vectors of the second, normalized format. In these embodiments, the message format converter 714 and format recovery circuit 730 are omitted.

When the values in the min-sum based non-binary LDPC decoder 700 converge and stabilize, or when a limit is reached on the number of local iterations, the variable node processor 702 provides the total LLR Sₙ(a) 734 to a decision circuit 736 to generate a hard decision 740 based on the argminₐ of the total LLR Sₙ(a).

The check node processor 704 includes a hard decision and parity memory circuit 750 that processes the interleaved normalized V2C message vectors 722 to provide the most likely symbol 752 to a select and combine circuit 754 having a number of elementary computation units (ECUs). The check node processor 704 also includes a min finder 756 that calculates the min₁(d), idx(d) and min₂(d) sub-messages 760 for each of the q symbols in the Galois Field and stores them in a min memory 762. The stored min₁(d), idx(d) and min₂(d) sub-messages 764 are provided by min memory 762 to the select and combine circuit 754. The select and combine circuit 754 combines the min₁(d), idx(d) and min₂(d) sub-messages 764 and the most likely symbol 752 to generate the C2V messages 724.

The message vector format conversion performed by message format converter 714 on V2C message vectors 712 is reversed by format recovery circuit 730, providing C2V messages 732 to variable node processor 702 in the format used by the variable node processor 702.

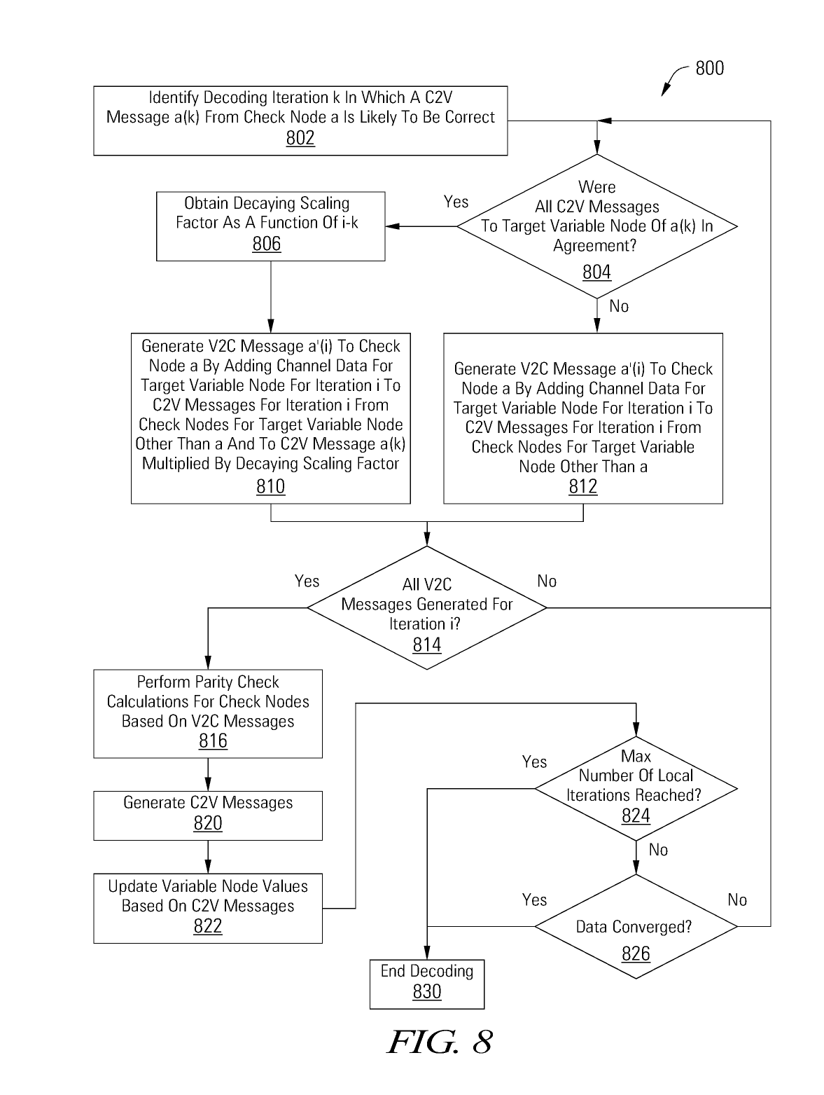

Turning to FIG. 8, a flow diagram 800 is depicted of a LDPC decoding operation with variable node hardening in accordance with various embodiments of the present inventions. Following flow diagram 800, the decoding iteration k in which a C2V message a(k) from check node a is likely to be correct is identified (block 802). This determination may be performed at design time to identify patterns as disclosed above with respect to FIG. 3 to help in selecting the iteration k when matching C2V messages m(k) indicate that variable node values are correct with high probability. In other embodiments, this determination may be performed during operation using quality metrics to identify an iteration k when C2V messages are likely correct with a higher probability than in other iterations. During the first local iteration of a global iteration, channel data are passed to check nodes as V2C messages because no C2V messages have yet been generated. The first C2V messages are therefore generated based just on channel data in V2C messages.

Blocks 804-812 are operations used to generate a V2C message a′(i) from a variable node to a check node a for iteration i. A determination is made (block 804) as to whether all C2V messages to the target variable node of C2V message a(k) were in agreement. If so, a decaying scaling factor is obtained (block 806) as a function of i−k, and in decoding iteration i, V2C message a′(i) to check node a is generated (block 810) by adding channel data for target variable node for iteration i to C2V messages for iteration i from check nodes for target variable node other than a and to C2V message a(k) multiplied by the decaying scaling factor. If not, in decoding iteration i, V2C message a′(i) to check node a is generated (block 812) by adding channel data for target variable node for iteration i to C2V messages for iteration i from check nodes for target variable node other than a. A determination is made (block 814) as to whether all V2C messages have been generated for iteration i. If not, the process of generating V2C messages continues (block 804). If so, parity check calculations are performed (block 816) for check nodes based on the V2C messages. C2V messages are generated (block 820). Variable node values are generated (block 822) based on the C2V messages. A determination is made (block 824) as to whether the maximum number of local iterations has been reached. If so, decoding is ended (block 830). Otherwise, a determination is made (block 826) as to whether the data converged. If so, decoding is ended (block 830). Otherwise, decoding iterations continue (block 804). When decoding is ended (block 830), this may be the end of decoding for a global iterations, or may be the end of overall decoding for a block or sector of data if the data converged, or if the maximum number of global iterations has been reached.

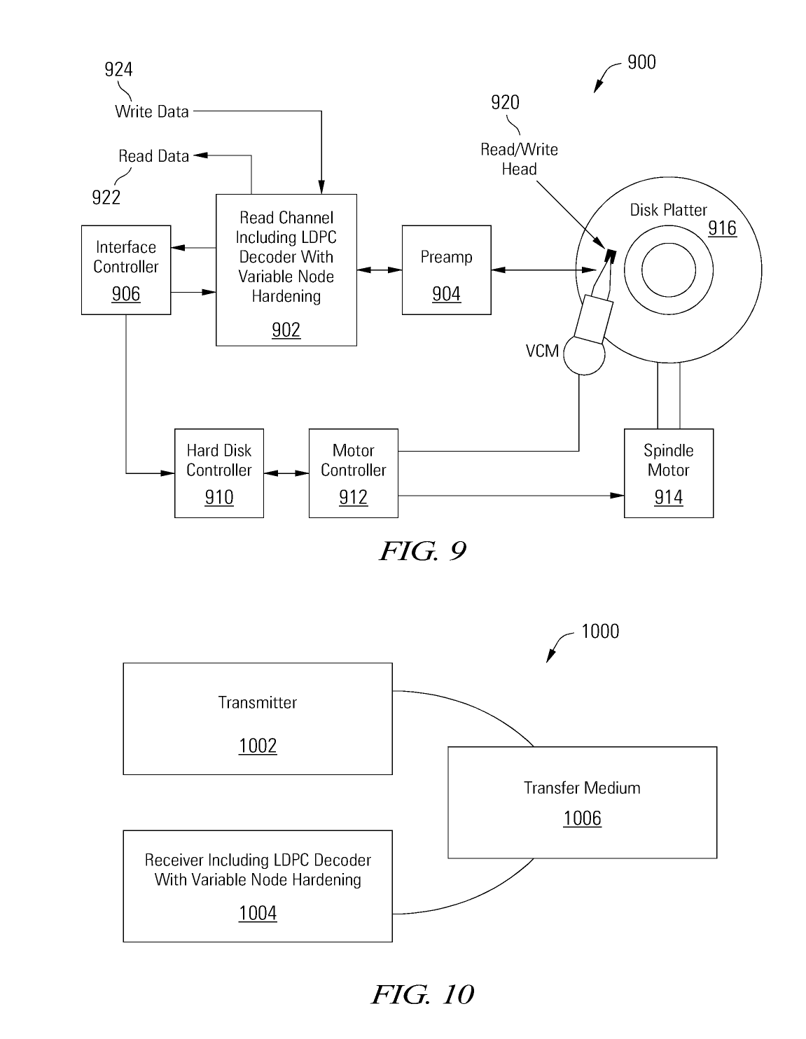

Although the LDPC decoder with variable node hardening disclosed herein is not limited to any particular application, several examples of applications are presented in FIGS. 9 and 10 that benefit from embodiments of the present inventions. Turning to FIG. 9, a storage system 900 including a read channel circuit 902 having an LDPC decoder with variable node hardening is shown in accordance with some embodiments of the present inventions. Storage system 900 may be, for example, a hard disk drive. Storage system 900 also includes a preamplifier 904, an interface controller 906, a hard disk controller 910, a motor controller 912, a spindle motor 914, a disk platter 916, and a read/write head 920. Interface controller 906 controls addressing and timing of data to/from disk platter 916. The data on disk platter 916 consists of groups of magnetic signals that may be detected by read/write head assembly 920 when the assembly is properly positioned over disk platter 916. In one embodiment, disk platter 916 includes magnetic signals recorded in accordance with either a longitudinal or a perpendicular recording scheme.

In a typical read operation, read/write head assembly 920 is accurately positioned by motor controller 912 over a desired data track on disk platter 916. Motor controller 912 both positions read/write head assembly 920 in relation to disk platter 916 and drives spindle motor 914 by moving read/write head assembly to the proper data track on disk platter 916 under the direction of hard disk controller 910. Spindle motor 914 spins disk platter 916 at a determined spin rate (RPMs). Once read/write head assembly 920 is positioned adjacent the proper data track, magnetic signals representing data on disk platter 916 are sensed by read/write head assembly 920 as disk platter 916 is rotated by spindle motor 914. The sensed magnetic signals are provided as a continuous, minute analog signal representative of the magnetic data on disk platter 916. This minute analog signal is transferred from read/write head assembly 920 to read channel circuit 902 via preamplifier 904. Preamplifier 904 is operable to amplify the minute analog signals accessed from disk platter 916. In turn, read channel circuit 902 decodes and digitizes the received analog signal to recreate the information originally written to disk platter 916. This data is provided as read data 922 to a receiving circuit. As part of decoding the received information, read channel circuit 902 processes the received signal using an LDPC decoder with variable node hardening. Such an LDPC decoder with variable node hardening may be implemented consistent with that disclosed above in relation to FIGS. 2-7. In some cases, LDPC decoding with variable node hardening may be performed consistent with the flow diagram disclosed above in relation to FIG. 8. A write operation is substantially the opposite of the preceding read operation with write data 924 being provided to read channel circuit 902. This data is then encoded and written to disk platter 916. It should be noted that various functions or blocks of storage system 900 may be implemented in either software or firmware, while other functions or blocks are implemented in hardware.

Storage system 900 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 900, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 10, a data transmission system 1000 including a receiver 1004 having an LDPC decoder with variable node hardening is shown in accordance with various embodiments of the present invention. Data transmission system 1000 includes a transmitter 1002 that is operable to transmit encoded information via a transfer medium 1006 as is known in the art. The encoded data is received from transfer medium 1006 by a receiver 1004. Receiver 1004 processes the received input to yield the originally transmitted data. As part of processing the received information, receiver 1004 decodes received data with an LDPC decoder with variable node hardening. Such an LDPC decoder with variable node hardening may be implemented consistent with that disclosed above in relation to FIGS. 2-7. In some cases, LDPC decoding with variable node hardening may be performed consistent with the flow diagram disclosed above in relation to FIG. 8.

It should be noted that the various blocks discussed in the above application may be implemented in integrated circuits along with other functionality. Such integrated circuits may include all of the functions of a given block, system or circuit, or a portion of the functions of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel systems, devices, methods and arrangements for an LDPC decoder with variable node hardening. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for decoding a low density parity check codeword comprising:
a check node processor operable to perform parity check calculations and to generate check node to variable node messages; and
a variable node processor operable to update variable node values based at least in part on the check node to variable node messages and to generate variable node to check node messages, and further operable to harden variable node to check node messages based on check node to variable node messages.

2. The apparatus of claim 1, the variable node processor is operable to harden the variable node to check node messages by generating the variable node to check node messages at least in part based on corresponding ones of the check node to variable node messages from a same edge between a variable node and a check node.

3. The apparatus of claim 1, wherein one of the variable node to check node messages is hardened by adding one of the check node to variable node messages along a same edge to said one of the variable node to check node messages.

4. The apparatus of claim 3, wherein said one of the check node to variable node messages is multiplied by a decaying scaling factor and added to said one of the variable node to check node messages in a plurality of successive decoding iterations.

5. The apparatus of claim 1, wherein the check node to variable node messages used to harden the variable node to check node messages are taken from a decoding iteration in which the check node to variable node messages are most likely to be correct.

6. The apparatus of claim 1, wherein the check node to variable node messages used to harden the variable node to check node messages are taken from a first local decoding iteration of each global decoding iteration.

7. The apparatus of claim 1, wherein the variable node to check node messages are only hardened when the check node to variable node messages used to harden the variable node to check node messages are all in agreement about a value of the source variable node for the corresponding variable node to check node messages.

8. The apparatus of claim 1, wherein the variable node processor is operable to generate a hardened variable node to check node message by adding a channel data value for a corresponding variable node for a current decoding iteration, at least one check node to variable node message for the current decoding iteration received by the corresponding variable node, and a weighted check node to variable node message taken from a same edge as the hardened variable node to check node message.

9. The apparatus of claim 8, wherein the variable node processor is operable to add the weighted check node to variable node message to hardened variable node to check node messages in a plurality of successive decoding iterations, and wherein a value of the weighted check node to variable node message diminishes with an increasing iteration number.

10. The apparatus of claim 1, wherein the apparatus is implemented as an integrated circuit.

11. The apparatus of claim 1, wherein the apparatus is incorporated in a storage device.

12. The apparatus of claim 11, wherein the storage device comprises a redundant array of independent disks.

13. The apparatus of claim 1, wherein the apparatus is incorporated in a transmission system.

14. A method for decoding a low density parity check codeword, comprising:
generating variable node to check node messages;
performing parity check calculations based on the variable node to check node messages;
generating check node to variable node messages based on the parity check calculations;
updating variable node values based on the check node to variable node messages; and
wherein at least some of the variable node to check node messages are based at least in part on some of the check node to variable node messages from a previous decoding iteration.

15. The method of claim 14, wherein the check node to variable node messages from the previous decoding iteration used to generate some of the variable node to check node messages are messages along a same edge between a same variable node and check node.

16. The method of claim 14, wherein basing at least some of the variable node to check node messages at least in part on some of the check node to variable node messages comprises weighting one of the check node to variable node messages from a same edge as the corresponding variable node to check node message with a decaying scaling factor to yield a scaled message and adding the scaled message to the corresponding variable node to check node message in a plurality of successive decoding iterations.

17. The method of claim 16, wherein the scaled message is added only when all check node to variable node messages for a source variable node for the corresponding variable node to check node message are in agreement about a value of the source variable node.

18. The method of claim 16, wherein the scaled message is derived from an iteration in which the check node to variable node messages are most likely to be correct.

19. The method of claim 16, wherein the scaled message is derived from a first local iteration of each global iteration.

20. A storage system comprising:
a storage medium maintaining a data set;
a read/write head assembly operable to sense the data set on the storage medium; and
a data processing circuit operable to correct errors in the data set, wherein the data processing circuit comprises an apparatus for decoding low density parity check codewords, comprising:
a check node processor operable to perform parity check calculations and to generate check node to variable node messages; and
a variable node processor operable to update variable node values based at least in part on the check node to variable node messages and to generate variable node to check node messages, and further operable to harden variable node to check node messages based on check node to variable node messages.
